(19) United States
(12) Patent Application Publication
(10) Pub. No.: US 2025/0366208 A1
(43) Pub. Date: Nov. 27, 2025

(54) CELL STRUCTURES AND SEMICONDUCTOR DEVICES HAVING SAME

(71) Applicant: TAIWAN SEMICONDUCTOR MANUFACTURING COMPANY, LTD., Hsinchu (TW)

(72) Inventors: Kuan-Ju LO, Taoyuan (TW); Yung Feng CHANG, Hsinchu (TW); Sen-Nien CHUNG, Hsinchu (TW); Shih-Yao YEN, Hsinchu (TW); Jiann-Tyng TZENG, Hsinchu (TW)

(21) Appl. No.: 18/673,374

(22) Filed: May 24, 2024

(51) Int. Cl. H01L 27/02; G06F 30/31

(52) U.S. Cl. CPC H10D 89/10; G06F 30/31

(57) ABSTRACT

A semiconductor device comprising active areas on substrate and arranged relative to an imaginary grid having first and second imaginary reference lines parallel to corresponding orthogonal first and second directions, the active areas are organized into instances of a first row having first conductivity and instances of a second row having second conductivity, each instance of first and second rows comprises a pre-determined number of first imaginary reference lines. The device includes a first cell region having a first instance of first row of the active area, and a second cell region having a first instance of second row of the active area, wherein the second cell region contacts the first cell region, and each first and second cell region has a first and second height, respectively, and a sum of first and second heights along the second direction represents a unit height of 1.5 times on the imaginary grid.

### BACKGROUND

An integrated circuit (“IC”) includes one or more semiconductor devices. One way to represent a semiconductor device is with a plan view diagram referred to as a layout diagram. A layout diagram is hierarchical and is decomposed into modules which carry out higher-level functions as indicated by the semiconductor device's design specifications. Continuous developments in semiconductor process technology nodes present a need to optimize the layout diagram for higher cell density in an IC.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1E are layout diagrams schematically illustrating various cell structures.

FIG. 2 is a diagram of an IC showing an exemplary arrangement of different cell regions.

FIGS. 3A-3D are layout diagrams schematically illustrating 1.5× height standard cell structures, in accordance with some embodiments of the present disclosure.

FIG. 4 illustrates a diagram of an IC showing an exemplary arrangement of different cell regions, in accordance with some embodiments of the present disclosure.

FIG. 5 is an enlarged view of a portion of the layout diagram of FIG. 4, in accordance with some embodiments.

FIG. 6 is a block diagram of an IC, in accordance with some embodiments of the present disclosure.

FIG. 7 is a flowchart of a method for generating a layout diagram of a standard cell, in accordance with some embodiments of the present disclosure.

FIG. 8 is a flowchart of a method for generating a layout diagram, in accordance with some embodiments of the present disclosure.

FIG. 9 is a block diagram of an electronic design automation (EDA) system that can be used to practice various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Traditional standard cell structures include logic gates and functions that have a standard or regular layout structure. The term “standard cell structure” refers to a standardized building block included in a library of various standard cell structures. In some embodiments, various standard cell structures are selected from a library thereof and are used as components in a layout diagram representing an integrated circuit. In the design of integrated circuits, standard cell structures having fixed functions are used. Pre-designed standard cell structures are stored in cell libraries. When designing integrated circuits, the standard cells are retrieved from the cell libraries and placed into desired locations on an integrated circuit layout. Routing is then performed to connect the standard cells with each other and with other cells using a routing grid which defines horizontal and vertical tracks where metal routing is formed. The tracks are used to route signal (interconnect) lines for passing signals between the cells. Typically, the direction of the fixed dimension is parallel to the vertical direction or Y-axis such that the fixed dimension is referred to as the height of the standard cell. Therefore, a standard cell's height can be determined by the number of horizontal grid lines extending between the uppermost and lowermost points of the cell, and the cell's width is determined by vertical grid lines (“poly pitches”) extending between the leftmost and rightmost points of the cell. To facilitate the placement and routing process, most cells of a standard cell library have the same height or a multiple thereof, and the uppermost and lowermost horizontal tracks are reserved for conductive lines. A smaller cell height results in a higher gate density with smaller transistors, while a larger cell height may be implemented to handle applications requiring more cell drive current.

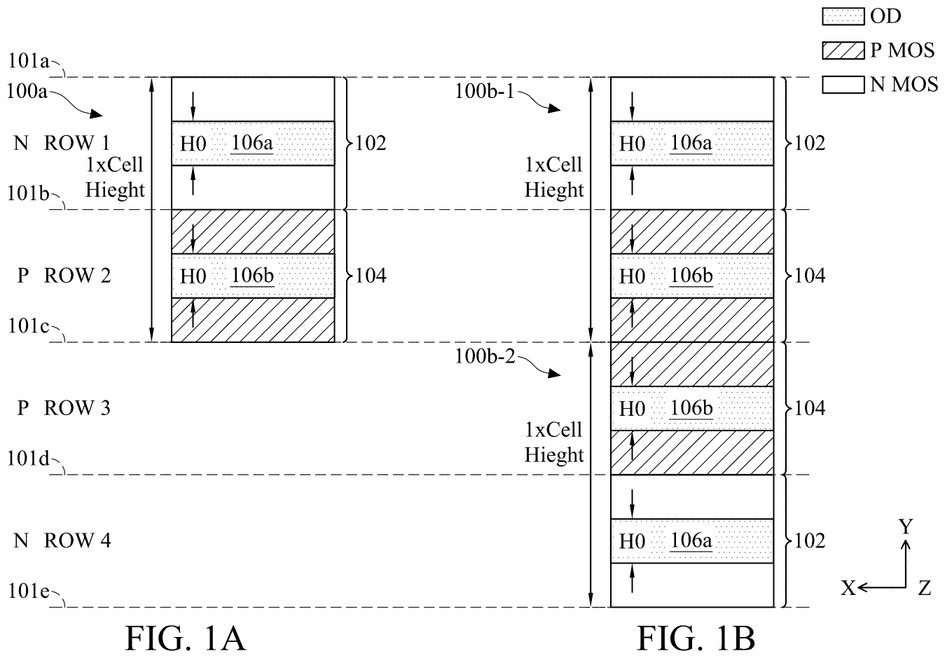

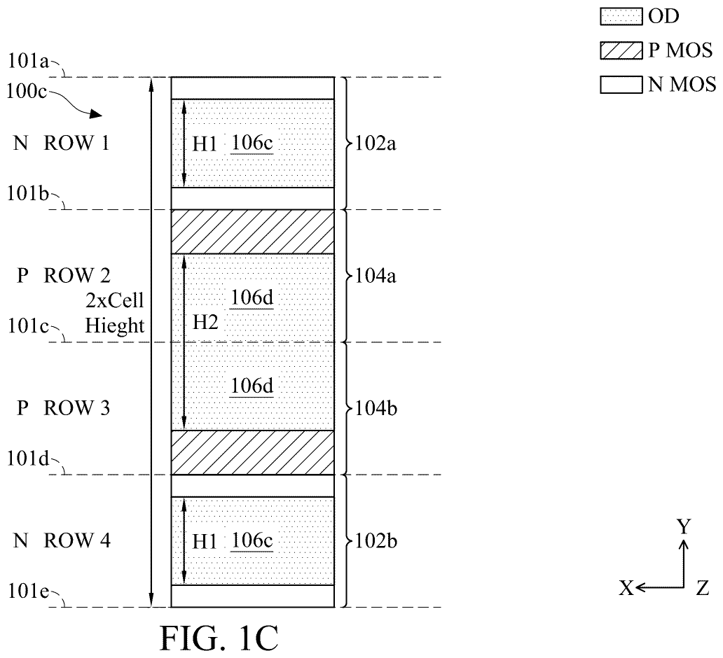

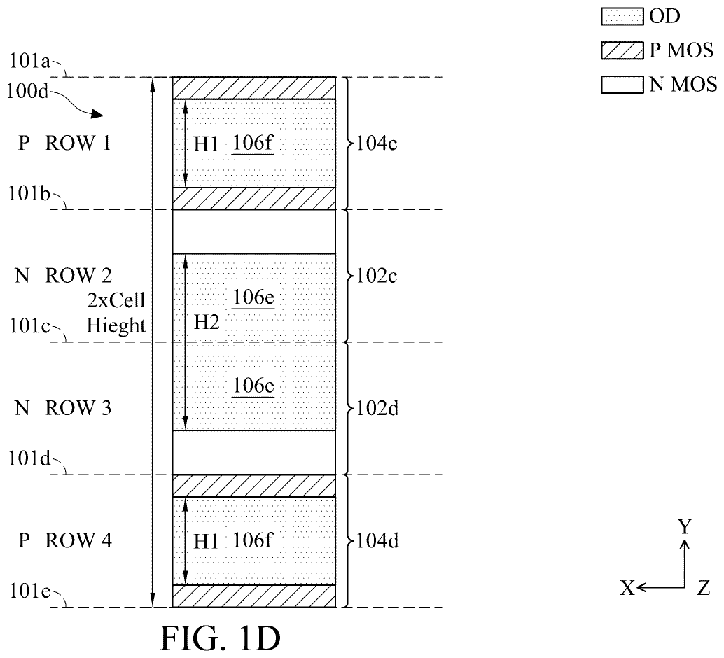

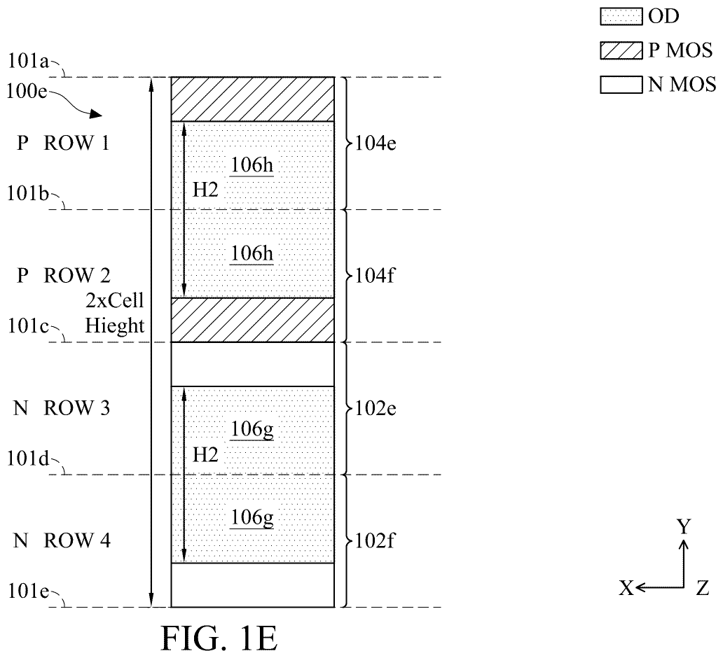

FIG. 1A is a layout diagram schematically illustrating a 1.0× height standard cell structure 100a in accordance with one example. A 1.0× height standard cell structure 100a includes one row configured for N-type cell region (e.g., NMOS) 102 and one row configured for P-type cell region (e.g., PMOS) 104, where the sum of the heights in the vertical direction (Y-direction) of the one NMOS row and the one PMOS row represents a unit height referred to as 1.0× on an imaginary grid having first and second imaginary reference lines which are substantially parallel to corresponding orthogonal first direction (e.g., X-direction) and second direction (e.g., Y-direction). The 1.0× height cell structure 100a includes two oxide diffusion (OD) areas or active areas 106a, 106b extending in the horizontal direction (X-direction), in which one OD region 106a is configured as N-type OD region and one OD region 106b is configured as P-type OD region. Therefore, the 1.0× height standard cell structure 100a is a single unit standard cell structure with two OD layout. The term “OD area or active area” in this disclosure refers to a fin area where source, drain, and channel under a gate of transistor are formed. The layout diagram in FIG. 1A is shown in the context of a plurality of imaginary reference lines 101a, 101b, 101c, 101d, 101e (collectively referred to as imaginary reference lines 101), which are equally separated in a parallel relationship along the Y-direction. As an example, the 1.0× height standard cell structure 100a has a top edge aligning with the imaginary reference line 101a and a bottom edge aligning with the imaginary reference line 101c. The 1.0× height standard cell structure 100a is divided by the imaginary reference line 101b into the NMOS row 102 and the PMOS row 104, in which an upper and lower boundary of each NMOS row 102 and PMOS row 104 is substantially collinear with a corresponding imaginary reference line 101 (e.g., imaginary reference lines 101a, 101b, 101c). In one example, each of the OD regions 106a, 106b has a width H0.

FIG. 1B is a layout diagram schematically illustrating two 1 time (1.0×) height standard cell structures 100b-1, 100b-2 stacking on one another in accordance with one example. In this example, an instance of uniform-width 1.0× height cell structure 100b-1 is stacked directly on an instance of uniform-width, 1.0× height cell structure 100b-2 relative to the vertical direction. Each 1.0× height standard cell structure 100b-1, 100b-2 is substantially identical to the 1.0× height standard cell structure 100a shown in FIG. 1A. The term “uniform-width” described herein in reference to a cell structure indicates that the width of the cell structure is uniform along the height of the cell structure. One of the N-type or P-type cell regions in the first 1.0× height standard cell structure 100a and one of the N-type or P-type cell regions in the second 1.0× height standard cell structure 100a can be configured to abut against each other. For example, a PMOS row in the first 1.0× height standard cell structure 100a may be arranged to abut against a PMOS row in the second 1.0× height standard cell structure 100a, resulting in an N-P-P-N arrangement along the vertical direction. Alternatively, a NMOS row in the first 1.0× height standard cell structure 100a may be arranged to abut against a NMOS row in the second 1.0× height standard cell structure 100a, resulting in a P-N-N-P arrangement along the vertical direction. In either case, the example in FIG. 1B is configured as a two-unit standard cell structure with four OD layout. In the examples of FIGS. 1A and 1B, the ratio of OD to cell height may be in a range of about 16% to about 44%.

To improve performance while complying with a design goal of preserving parity in the number of NMOS rows and PMOS rows, a 2 times (2.0×) height standard cell structure can be used. 2.0× height standard cell structures provide higher OD density, which increases total surface area of OD regions for higher power, and thus better device performance. FIG. 1C is a layout diagram schematically illustrating a 2.0× height standard cell structure 100c in accordance with one example. The 2.0× height standard cell structure 100c may be obtained by expanding the 1.0× height standard cell structure. Alternatively, the 2.0× height standard cell structure 100c can be achieved by increasing the surface area of the OD region (e.g., double the size) in each NMOS row 102 and PMOS row 104 shown in FIG. 1B. In one example, the OD region in each NMOS row 102a, 102b has a width H1 that is greater than the width H0 of the OD region 106a of the NMOS row 102. In one example, the 2.0× height standard cell structure 100c includes two NMOS rows 102a, 102b and two PMOS rows 104a, 104b that are configured in an N-P-P-N arrangement. Particularly, the OD region 106c, 106d in each NMOS 102a, 102b and PMOS row 104a, 104b is respectively configured to be twice the size of the OD region 106a, 106b shown in FIG. 1B.

In some examples, the PMOS rows 104a, 104b are arranged to abut against each other, making the OD regions 106d in the PMOS rows 104a, 104b a single OD region expanding across the imaginary reference line 101c and between the imaginary reference lines 101b and 101d. In such cases, the 2.0× height standard cell structure 100c is a 2.0× height standard cell with three OD layout, which includes two NMOS rows and one PMOS row arranged in a continuous manner along the vertical direction. The combined OD regions 106d in the PMOS rows 104a, 104b have a width H2 that is greater than (e.g., about 2 times bigger) the width H1 of the OD region 106c in each NMOS 102a, 102b. As an example, the 2.0× height standard cell structure 100c has a top edge aligning with the imaginary reference line 101a and a bottom edge aligning with the imaginary reference line 101c. The 2.0× height standard cell structure 100c is divided by the imaginary reference lines 101b and 101d into two NMOS rows 102a, 102b and one PMOS row 204.

FIG. 1D is a layout diagram schematically illustrating a 2.0× height standard cell structure 100d in accordance with another example. In this example, the 2.0× height standard cell structure 100d includes two NMOS rows 102c, 102d and two PMOS rows 104c, 104d that are configured in a P-N-N-P arrangement. Particularly, the OD region 106e, 106f in each NMOS 102c, 102d and PMOS row 104c, 104d is respectively configured to be twice the size of the OD region 106a, 106b shown in FIG. 1B. The example shown in FIG. 1D is substantially identical to the example shown in FIG. 1C except that the NMOS rows 102c, 102d are arranged to abut against each other, making the OD regions 106e in the NMOS rows 102c, 102d a single OD region expanding across the imaginary reference line 101c and between the imaginary reference lines 101b, 101d. Therefore, the 2.0× height standard cell structure 100d is a 2.0× height standard cell with three OD layout, which includes two PMOS rows and one NMOS row arranged in a continuous manner along the vertical direction.

Likewise, the combined OD regions 106e in the NMOS rows 102c, 102d has a width H2 that is greater than the width H1 of the OD region 106f in each PMOS 104c, 104d. The enlargement of the OD regions in either N-type cell region or P-type cell region of FIGS. 1C and 1D allows the ratio of OD to cell height to be improved from about the range of about 16% to about 44% (FIGS. 1A and 1B) to the range of about 37.5% to about 46.5%.

FIG. 1E is a layout diagram schematically illustrating a 2.0× height standard cell structure 100e in accordance with one another example. FIG. 1E is a variation of the example shown FIG. 1D by combining and rearranging two PMOS rows 104c, 104d in FIG. 1D so that two PMOS rows 104c, 104d are disposed immediately adjacent the two NMOS rows 102c, 102d. In this example, the 2.0× height standard cell structure 100e includes two PMOS rows 104e, 104f and two NMOS rows 102e, 102f that are configured in a P-P-N-N arrangement. Similarly, the OD region 106g, 106h in each NMOS row 102e, 102f and the OD region 106h in each PMOS row 104e, 104f are respectively configured to be twice the size of the OD region 106a, 106b shown in FIG. 1B. Particularly, the two NMOS rows 102e, 102f are arranged to abut against each other, making the OD regions 106g in the NMOS rows 102e, 102f a single OD region expanding across the imaginary reference line 101d and between the imaginary reference lines 101c and 101e.

Likewise, the two PMOS rows 104e, 104f are arranged to abut against each other, making the OD regions 106h in the PMOS rows 104e, 104f a single OD region expanding across the imaginary reference line 101b and between the imaginary reference lines 101a, 101c. In such cases, the 2.0× height standard cell structure 100e is a 2.0× height standard cell with two OD layout, which includes one NMOS and one PMOS arranged in a continuous manner along the vertical direction. The combined OD regions 106h in the two PMOS rows 104e, 104f has a width H2 that is greater than the width H1 of the OD region 106g in each NMOS row 102e, 102f. As an example, the 2.0× height standard cell structure 100e has a top edge aligning with the imaginary reference line 101a and a bottom edge aligning with the imaginary reference line 101e. The 2.0× height standard cell structure 100e is divided by the imaginary reference lines 101c into one NMOS 102e, 102f and one PMOS 104e, 104f. The enlargement of the OD regions in both N-type cell region and P-type cell region of FIG. 1E allows the ratio of OD to cell height to be improved from about the range of about 37.5% to about 46.5% (FIGS. 1C and 1D) to the range of about 38.5% to about 46.5%.

An integrated circuit generally includes a plurality of semiconductor devices each of which may have a circuit region with a layout diagram different than the layout diagram in other circuit regions. To facilitate the placement and routing process, a set of design rules may impose constraints on the placement of circuit regions, e.g., geographic/spatial restrictions, connectivity restrictions, or the like. In many cases, the design rules may prevent certain circuit regions from being placed immediately adjacent to other circuit regions when circuit regions with different layout diagrams (and different OD widths) are placed together on an integrated circuit. For example, a direct stacking of a 1.0× standard cell structure (e.g., the 1.0× standard cell structure 100a of FIG. 1a) on a 2.0× standard cell structure (e.g., the 2.0× standard cell structure 100e of FIG. 1E) is not permitted. However, the 1.0× standard cell structure is permitted to be positioned adjacent to the 2.0× standard cell structure if a dummy OD region is disposed between the 1.0× standard cell structure and the 2.0× standard cell structure. The term “dummy OD region” herein refers to areas or fin structures that are not doped for a particular conductivity. In some embodiments, the dummy OD region is included and/or located to provide isolation between two active regions. The use of dummy OD regions allows different standard cell structures to be placed together on the IC having cell regions arranged in a specific order of conductivity type.

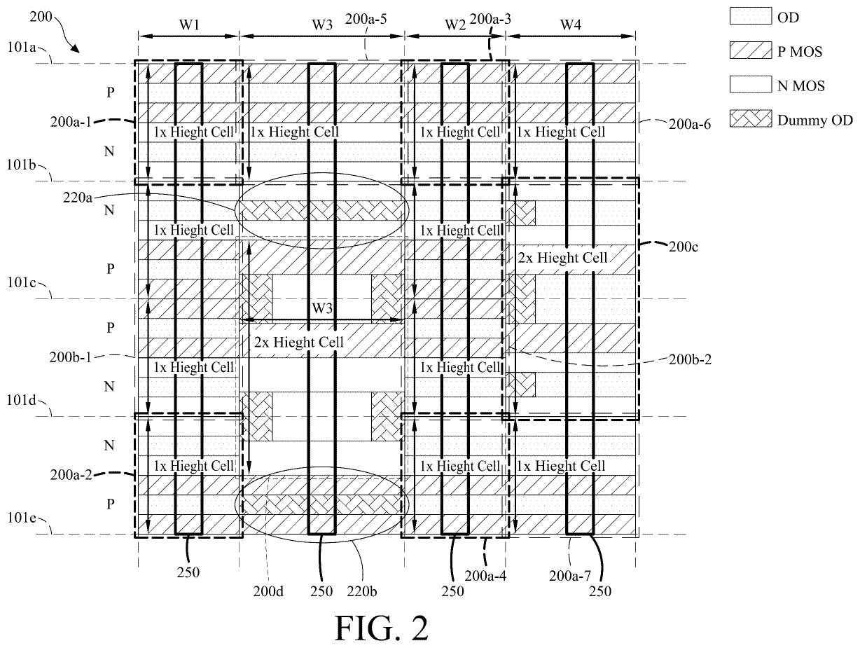

FIG. 2 is a diagram of an IC 200 showing an exemplary arrangement of different cell regions. As will be discussed in more detail below, cell regions with various layout diagrams are arranged in a pre-determined P-N-N-P-P-N-N-P stack architecture along the Y-direction in the context of a plurality of imaginary reference lines 101a, 101b, 101c, 101d, 101e (collectively referred to as imaginary reference lines 101), which extend in a parallel relationship with respect to the X-direction. In one example, the IC 200 includes a two-unit 1.0× height standard cell structure 200b-1 (e.g., two-unit 1.0× height standard cell structure 100b-1, 100b-2 shown in FIG. 1B) disposed between two 1.0× height standard cell structure 200a-1, 200a-2 (e.g., 1.0× height standard cell structure 100a shown in FIG. 1A), all of which have a cell width W1; a two-unit 1.0× height standard cell structure 200b-2 (e.g., two-unit 1.0× height standard cell structure 100b-1, 100b-2 shown in FIG. 1B) disposed between two 1.0× height standard cell structure 200a-3, 200a-4 (e.g., 1.0× height standard cell structure 100a shown in FIG. 1A), all of which have a cell width W2 equal to the cell width W1; a 2.0× height standard cell structure 200d (e.g., 2.0× height standard cell structure 100e shown in FIG. 1E) disposed between the two-unit 1.0× height standard cell structures 200b-1, 200b-2 and below a 1.0× height standard cell structure 200a-5 (e.g., 1.0× height standard cell structure 100a shown in FIG. 1A), all of which have a cell width W3 greater than the widths W1 and W2, respectively; and a 2.0× height standard cell structure 200c (e.g., 2.0× height standard cell structure 100c shown in FIG. 1C) disposed adjacent the two-unit 1.0× height standard cell structure 200b-2 and between two 1.0× height standard cell structure 200a-6, 200a-7 (e.g., 1.0× height standard cell structure 100a shown in FIG. 1A), all of which have a cell width W4 equal to the cell width W3.

Instances of gate patterns 250 are arranged over the OD regions along the Y-direction. While not shown, source/drain features may be disposed on opposite sides of the gate patterns 250.

As can be seen in FIG. 2, if the 1.0× height standard cell structure 200a-3 were to combine with the 2.0× height standard cell structure 200d under the pre-determined P-N-N-P-P-N-N-P stack architecture, a white space (i.e., dummy OD region) is required to be placed between the 1.0× height standard cell structure 200a-3 and the 2.0× height standard cell structure 200d. That is, the dummy OD regions 220a, 220b (highlighted in circles) are needed to enable close placement of the 1.0× height standard cell structure 200a-3 to the 2.0× height standard cell structure 200d. Since each dummy OD region 220a, 220b represents 0.5× height dummy area, the presence of the dummy OD regions 220a, 220b would take up space that is otherwise available for standard cell structures. Therefore, the total surface area of the OD in active regions of the IC is affected, hence the performance degradation of the device.

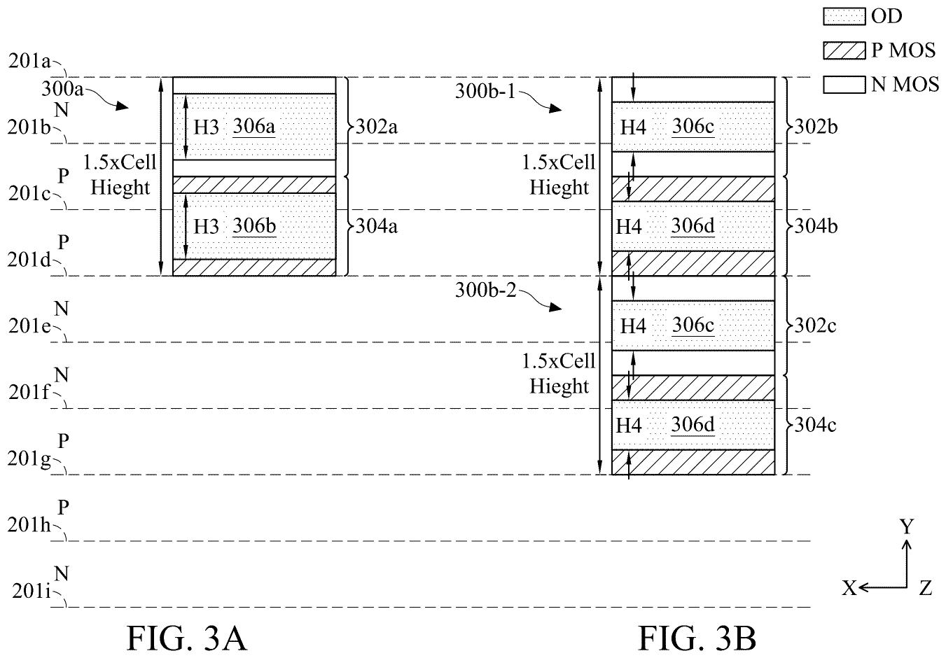

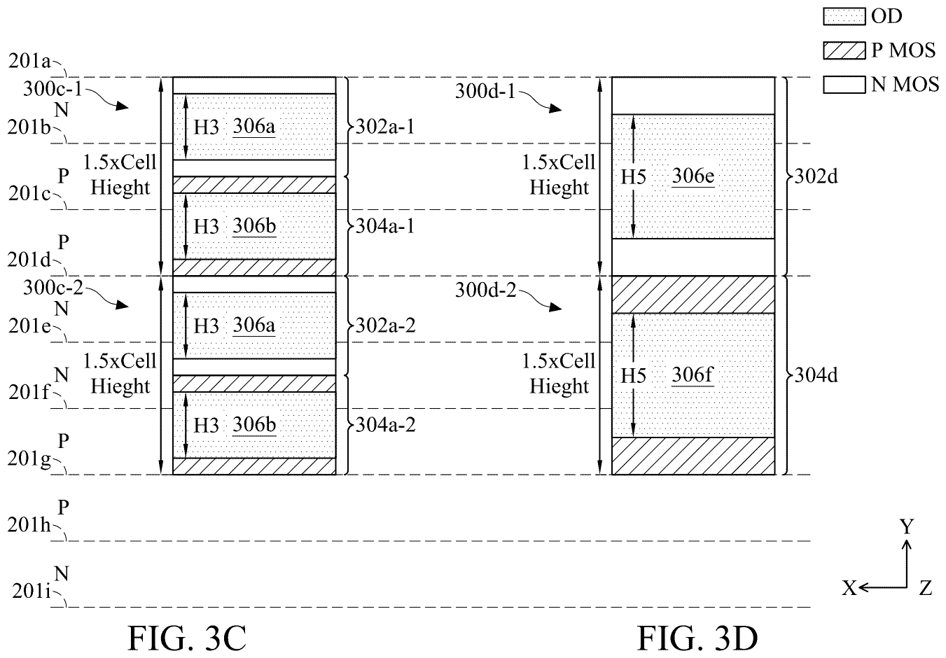

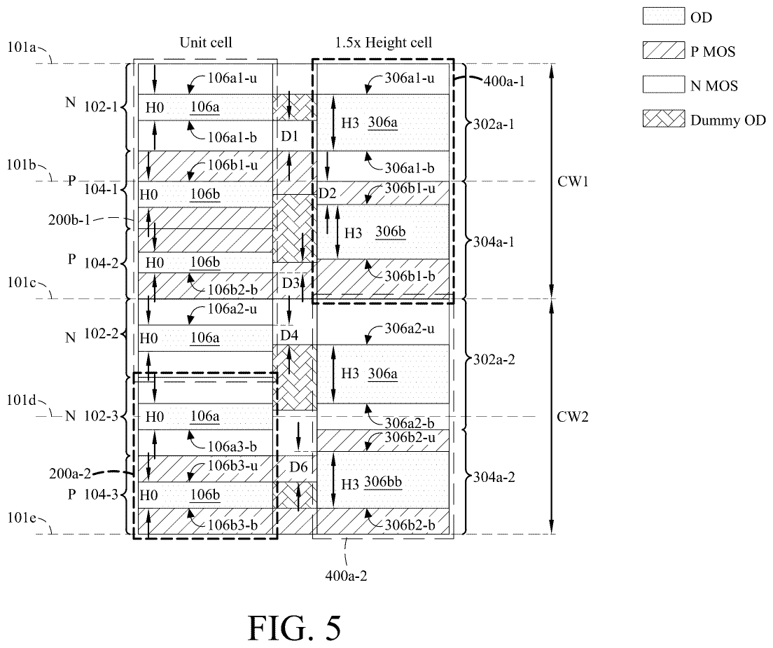

To optimize different combinations of cell regions on an IC, the inventors of the present disclosure propose combining a 1.5× height standard cell structure with 1.0× height standard cell structures in a layout diagram, as will be discussed in more detail in FIG. 5. FIGS. 3A-3D are layout diagrams schematically illustrating a 1.5× height standard cell structure, in accordance with some embodiments of the present disclosure. The 1.5× height standard cell structures shown in FIGS. 3A-3D are used as standard cell structures in a library of standard cell structures. The cell regions in FIGS. 3A-3D can be arranged in a prefixed or pre-determined N-P-P-N-N-P-P-N stack architecture along the Y-direction in the context of a plurality of imaginary reference lines 201a, 201b, 201c, 201d, 201e, 201f, 201g, 201h, 201i (collectively referred to as imaginary reference lines 201), which are equally separated in a parallel relationship along the Y-direction. In FIGS. 3A-3D, a stacking direction is parallel to the vertical direction. In some embodiments, rotation of the 1.5× height standard cell structures is contemplated, resulting in stacking directions other than the vertical direction.

In FIG. 3A, the 1.5× height standard cell structure 300a includes one instance of a cell region 302a configured for N-type cell region (e.g., NMOS) and one instance of a cell region 304a configured for P-type cell region (e.g., PMOS) 104, where the sum of the heights in the vertical direction (Y-direction) of the one NMOS and the one PMOS represents a unit height of 1.5 times (1.5×) on an imaginary grid having first and second imaginary reference lines which are substantially parallel to corresponding orthogonal first direction (e.g., X-direction) and second direction (e.g., Y-direction). As an example, the 1.5× height standard cell structure 300a has a top edge aligning with the imaginary reference line 201a and a bottom edge aligning with the imaginary reference line 201d. The 1.5× height cell structure 300a includes OD areas or active areas 306a, 306b extending in the horizontal direction (X-direction), in which one OD area 306a is configured as N-type OD region and one OD area 306b is configured as P-type OD region. Therefore, the 1.5× height standard cell structure 100a is a single unit standard cell structure with two OD layout.

Compared to the 1.0× height standard cell structure (e.g., the 1.0× height standard cell structure 100a shown in FIG. 1A), the 1.5× height standard cell structure 300a expands about 12.5% more surface area. Particularly, the surface area of each OD region 306a, 306b is increased by about 50% when compared to the 1.0× height standard cell structure. In one embodiment, the OD region in the NMOS region 302a and the PMOS region 304a have a width H3 that is greater than the width H0 of the OD region 106a of the NMOS row 102 in the 1.0× height standard cell structure 100a shown in FIG. 1A.

FIG. 3B is a layout diagram schematically illustrating two 1.5× height standard cell structures 300b-1, 300b-2, in accordance with some alternative embodiments. In this embodiment, each 1.5× height standard cell structures 300b-1, 300b-2 includes two cell regions 302b, 302c configured for N-type cell region (e.g., NMOS) and two cell regions 304b, 304c configured for P-type cell region (e.g., PMOS). In one embodiment, an instance of uniform-width 1.5× height cell structure 300b-1 is stacked directly on an instance of uniform-width, 1.5× height cell structure 300b-2 relative to the vertical direction. In some embodiments, each 1.5× height standard cell structure 300b-1, 300b-2 is substantially identical to the 1.5× height standard cell structure 300a shown in FIG. 3A. In some embodiments, one of the N-type or P-type cell regions in the first 1.5× height standard cell structure 300b-1 and one of the N-type or P-type cell regions in the second 1.5× height standard cell structure 300b-2 can be configured to abut against each other. For example, a PMOS region 304b (or NMOS region 302b) in the first 1.5× height standard cell structure 300b-1 may be arranged to abut against a NMOS region 302c (or PMOS region 304c) in the second 1.5× height standard cell structure 300b-2. In such cases, the 1.5× height standard cell structures 300b-1, 300b-2 include two NMOS regions 302b, 302c and two PMOS regions 304b, 304c that are configured in an N-P-N-P arrangement. Particularly, each of the first 1.5× height standard cell structure 300b-1 and the second 1.5× height standard cell structure 300b-2 includes an OD area or active area that is less than the OD area or active area of the NMOS region 302a and the PMOS region 304a in the 1.5 height standard cell structure 300a shown in FIG. 3A. As an example, the 1.5× height standard cell structure 300b-1 has a top edge aligning with the imaginary reference line 201a and a bottom edge aligning with the imaginary reference line 201d, and the 1.5× height standard cell structure 300b-2 has a top edge aligning with the imaginary reference line 201d and a bottom edge aligning with the imaginary reference line 201g.

In some embodiments, the OD region 306c in each of the NMOS regions 302b, 302c may have a width H4 that is smaller than the width H3 of the OD region 306a, 306b of the NMOS region 302a and the PMOS region 304a in the 1.5 height standard cell structure 300a, wherein the width H4 is greater than the width H0 of the OD region 106a of the NMOS row 102 in the 1.0× height standard cell structure 100a shown in FIG. 1A.

FIG. 3C is a layout diagram schematically illustrating two 1.5× height standard cell structures 300c-1, 300c-2 stacking on one another, in accordance with some alternative embodiments. In this embodiment, an instance of uniform-width 1.0× height cell structure 300c-1 is stacked directly on an instance of uniform-width, 1.5× height cell structure 300c-2 relative to the vertical direction. Each 1.5× height standard cell structure 300c-1, 300c-2 is substantially identical to the 1.5× height standard cell structure 300a shown in FIG. 3A. The 1.5× height standard cell structure 300c-1 has a NMOS region 302a-1 and a PMOS region 304a-1, and the 1.5× height standard cell structure 300c-2 has a NMOS region 302a-2 and a PMOS region 304a-2. The NMOS regions 302a-1, 302a-2 and the PMOS regions 304a-1, 304a-2 are approximately arranged in a pre-determined N-P-P-N-N-P stack architecture along the Y-direction in the context of a plurality of imaginary reference lines 201a, 201b, 201c, 201d, 201e, 201f, 201g. As an example, the 1.5× height standard cell structure 300c-1 has a top edge aligning with the imaginary reference line 201a and a bottom edge aligning with the imaginary reference line 201d, and the 1.5× height standard cell structure 300c-2 has a top edge aligning with the imaginary reference line 201d and a bottom edge aligning with the imaginary reference line 201g.

In some embodiments, the NMOS region 302a-1 in the first 1.5× height standard cell structure 300c-1 has an OD region 306a expanding across the imaginary reference line 201b, and the PMOS region 304a-1 in the first 1.5× height standard cell structure 300c-1 has an OD region 306b expanding across the imaginary reference line 201c. The NMOS region 302a-2 in the second 1.5× height standard cell structure 300c-2 has an OD region 306a expanding across the imaginary reference line 201e, and the PMOS region 304a-2 in the second 1.5× height standard cell structure 300c-2 has an OD region 306b expanding across the imaginary reference line 201f. Each NMOS region 302a-1, 302a-2 and each PMOS region 304a-1, 304a-2 has a width H3 that is identical to the width H3 of the NMOS/PMOS region 302a, 304a of the 1.5× height standard cell structure 300a shown in FIG. 3A.

FIG. 3D is a layout diagram schematically illustrating two 1.5× height standard cell structures 300d-1, 300d-2, in accordance with some alternative embodiments. The embodiment shown in FIG. 3D can be realized by combining the two NMOS regions 302a-1, 302a-2 and two PMOS regions 304a-1, 304a-2 shown in FIG. 3C, making it a two-unit 1.5× height standard cell structure with two OD layout. In some embodiments, the 1.5× height standard cell structure 300d-1 has a top edge aligning with the imaginary reference line 201a and a bottom edge aligning with the imaginary reference line 201d, with the OD region 306e expanding across over the imaginary reference line 201b and the imaginary reference line 201c. The 1.5× height standard cell structure 300d-2 has a top edge aligning with the imaginary reference line 201d and a bottom edge aligning with the imaginary reference line 201g, with the OD region 306f expanding across over the imaginary reference line 201e and the imaginary reference line 201f. Each of the 1.5× height standard cell structures 300d-1, 300d-2 has a width H5 that is greater than (e.g., about 2 times greater) the width H3 of the NMOS/PMOS region 302a, 304a shown in FIG. 3A. In various embodiments of FIGS. 3A-3D, the ratio of OD to cell height can be increased to a range of about 46% to about 51.5%.

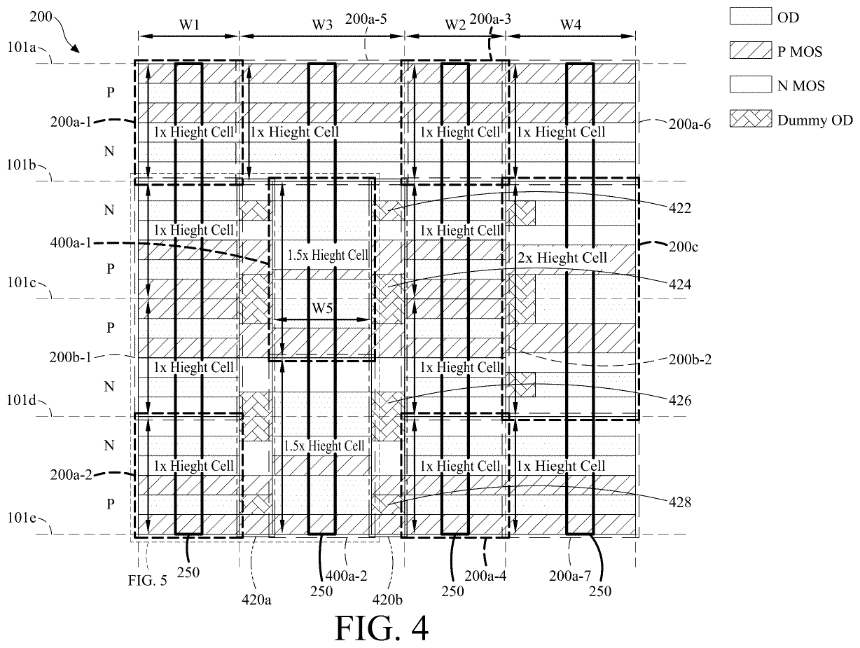

The use of 1.5× height standard cell structures is advantageous for optimization of cell combination in a diagram of an IC as it allows direct abutment with standard cell structures having different cell heights and/or OD widths with reduced or minimal dummy area. FIG. 4 illustrates a diagram of an IC 400 showing an exemplary arrangement of different cell regions, in accordance with some embodiments of the present disclosure. The embodiments shown in FIG. 4 is substantially identical to those shown in FIG. 2 except that the 2.0× height standard cell structure 200d is being replaced with two 1.5× height standard cell structures 400a-1, 400a-2, such as the 1.5× height standard cell structures 300c-1, 300c-2 shown in FIG. 3C. For the sake of brevity, the discussion of FIG. 4 will focus on differences due to the use of the 1.5× height standard cell structures.

As can be seen in FIG. 4, the two-unit 1.0× height standard cell structures 200b-1, 200b-2 and the 1.0× height standard cell structures 200a-2, 200a-4 are arranged in a pre-determined N-P-P-N-N-P stack architecture along the Y-direction in the context of a plurality of imaginary reference lines 101b, 101c, 101d, 101e. The two 1.5× height standard cell structures 400a-1, 400a-2 can be placed between the two-unit 1.0× height standard cell structures 200b-1, 200b-2 and the 1.0× height standard cell structures 200a-2, 200a-4, respectively, due to their similar or identical arrangement of the stack architecture in a pre-determined N-P-P-N-N-P along the Y-direction in the context of a plurality of imaginary reference lines 101b, 101c, 101d, 101e. Particularly, the 1.0× height standard cell structure 200a-5 is contiguous in the vertical direction with the 1.5× height standard cell structure 400a-1, resulting in a reduced dummy area (e.g., dummy OD regions 420a, 420b) when compared to the example shown in FIG. 2. Furthermore, the sum of the heights (in the Y-direction) of the two 1.5× height standard cell structures 400a-1, 400a-2 is now a combined height of 3×, which reduces the surface area of the dummy area. Therefore, the use of the two-unit 1.0× height standard cell structures 200b-1, 200b-2 increases the total number of the OD regions (from a 2 OD layout to a 4 OD layout) and the total surface area of the active OD regions (e.g., from OD regions 106h, 106g in FIG. 1E to OD regions 306a, 306b in FIG. 3C) within a given surface area.

In cases where the two 1.5× height standard cell structures 400a-1, 400a-2 have a uniform-cell width W5 that is less than the cell width W3 of the 1.0× height standard cell structure 200a-5, the dummy area (i.e., dummy OD regions 420a, 420b) may remain on either side of the two 1.5× height standard cell structures 400a-1, 400a-2 with a reduced footage when compared to the example shown in FIG. 2. When the dummy area is reduced, the available space for OD regions in the active regions is increased. As a result, the performance of the device is improved.

In some embodiments, the 1.5× height standard cell structures 400a-1, 400a-2 are a version of the 1.5× height standard cell structures 300c-1, 300c-2 shown in FIG. 3C such that (1) the NMOS region 302a-1 has two opposing sides in contact with a first dummy OD region 422, wherein the upper boundary of the first dummy OD region 422 is substantially collinear with the upper boundary of the NMOS region 302a-1, and the bottom boundary of the first dummy OD region 422 and the bottom boundary of the NMOS region 302a-1 are non-coplanar; (2) the PMOS region 304a-1 has two opposing sides in contact with a second dummy OD region 424, wherein the upper boundary of the second dummy OD region 424 and the upper boundary of the PMOS 304a-1 are non-coplanar, and the bottom boundary of the second dummy OD region 424 is substantially collinear with the bottom boundary of the PMOS region 304a-1; (3) the NMOS region 302a-2 has two opposing sides in contact with a third dummy OD region 426, wherein the upper boundary of the third dummy OD region 426 is substantially collinear with the upper boundary of the NMOS region 302a-2, and the bottom boundary of the third dummy OD region 426 and the bottom boundary of the NMOS region 302a-2 are non-coplanar; and (4) the PMOS region 304a-2 has two opposing sides in contact with a fourth dummy OD region 428, wherein the upper boundary of the fourth dummy OD region 428 and the upper boundary of the PMOS region 304a-2 are non-coplanar, and the bottom boundary of the fourth dummy OD region 428 and the bottom boundary of the PMOS region 304a-2 are substantially collinear.

FIG. 5 is an enlarged view of a portion of the layout diagram of FIG. 4, in accordance with some embodiments. As can be seen in FIG. 5, while the two-unit 1.0× height standard cell structure 200b-1 and the 1.0× height standard cell structures 200a-2 are similarly arranged in a pre-determined N-P-P-N-N-P stack architecture along the Y-direction to the two 1.5× height standard cell structures 400a-1, 400a-2, the different OD width between the two may result in various transition gaps D1-D6. In some embodiments, the OD region 306a of the NMOS region 302a-1 in the first 1.5× height standard cell structures 400a-1 may have a width H3 that is greater than the width H0 of the OD region 106a of the NMOS region 102 in the two-unit 1.0× height standard cell structure 200b-1. The upper boundary 306a1-u of the OD region 306a and the upper boundary 106a1-u of the OD region 106a are substantially co-planar, and the bottom boundary 306a1-b of the OD region 306a may be offset from the bottom boundary 106a1-b of the OD region 106a of the NMOS region 102-1 by a transition gap D1.

In some embodiments, the OD region 306b of the PMOS region 304a-1 in the first 1.5× height standard cell structures 400a-1 may have a width H3 that is greater than the width H0 of the OD region 106b of the PMOS regions 104-1 in the two-unit 1.0× height standard cell structure 200b-1. The upper boundary 306b1-u of the OD region 306b of the PMOS region 304a-1 may be offset from and the upper boundary 106b1-u of the OD region 106b of the PMOS region 104-1 by a transition gap D2, and the bottom boundary 306b1-b of the OD region 306b of the PMOS region 304a-1 may be offset from the bottom boundary 106b2-b of the OD region 106b of the PMOS region 104-2 by a transition gap D3.

In some embodiments, the OD region 306a of the NMOS region 302a-2 in the second 1.5× height standard cell structures 400a-2 may have a width H3 that is greater than the width H0 of the OD region 106a of the NMOS regions 102-2 in the two-unit 1.0× height standard cell structure 200b-1. The upper boundary 306a2-u of the OD region 302a-2 of the NMOS region 302a-2 may be offset from and the upper boundary 106a2-u of the OD region 106a of the NMOS region 102-2 by a transition gap D4, and the bottom boundary 306a2-b of the OD region 306a of the NMOS region 302a-2 may be offset from the bottom boundary 106a3-b of the OD region 106a of the NMOS region 102-3 of the 1.0× height standard cell structures 200a-2 by a transition gap D5.

In some embodiments, the OD region 306b of the PMOS region 304a-2 in the second 1.5× height standard cell structures 400a-2 may have a width H3 that is greater than the width H0 of the OD region 106b of the PMOS region 104-3 in the 1.0× height standard cell structures 200a-2. The upper boundary 306b2-u of the OD region 306b may be offset from the upper boundary 106b3-u of the OD region 106b of the PMOS region 104-3 by a transition gap D6, and the bottom boundary 306b2-b and the bottom boundary 106b3-b of the OD region 106b of the PMOS region 104-3 are substantially co-planar.

In some embodiments, the transition gap D1 is greater than the transition gap D2, and the transition gap D2 is greater than the transition gap D3. The transition gap D4 is less than the transition gap D5, and the transition gap D5 is less than the transition gap D6. In some embodiments, the transition gap D1 and the transition gap D6 is substantially the same. In various embodiments, each of the transition gaps D1, D2, and D3 may be about 0% to about 22% of cell height width CW1 of the first 1.5× height standard cell structure 400a-1. Likewise, each of the transition gaps D4, D5, and D6 may be about 0% to about 22% of cell height width CW2 of the second 1.5× height standard cell structure 400a-2. The greater the transition gap, the greater flexibility for the 1.5× height standard cell structures 400a-1, 400a-2 to abut with single-unit or two-unit 1.0× height standard cell structures with different OD heights, and therefore a better device's performance.

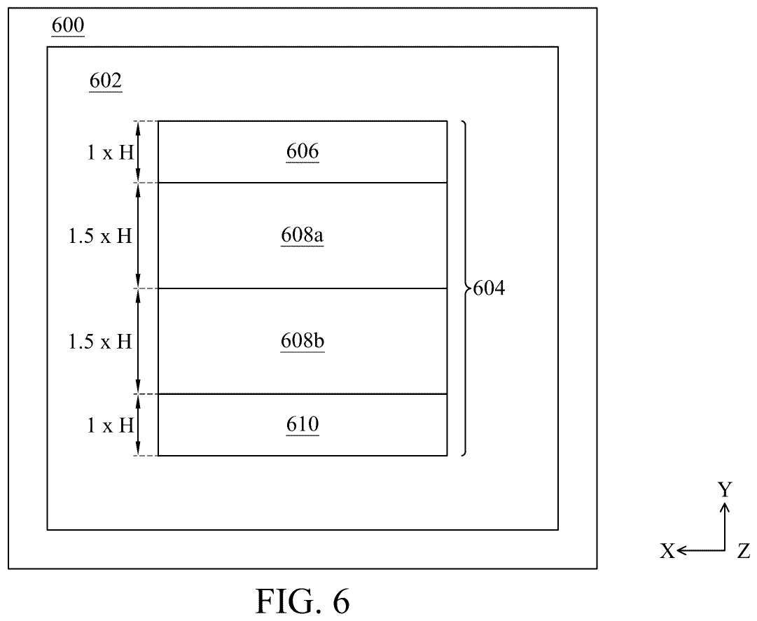

FIG. 6 is a block diagram of an IC 600, in accordance with some embodiments of the present disclosure. The IC 600 includes a semiconductor device 602 with at least one circuit region 604. The IC 600 may be referred to as a chip or a micro-chip, which can be a set of electronic circuits on a substrate formed from a semiconductor material, such as silicon. The IC 600 may include one or more transistors, such as planar FETs, FinFETs, Horizontal Gate All Around (HGAA) FETs, Vertical Gate All Around (VGAA) FETs, nanosheet FETs, and other suitable devices, integrated into a chip. The IC 600 is electrically coupled to, incorporates or houses one or more semiconductor devices 602. Circuit region 604 may include two single unit standard cell structures 606, 610, each of which may be the 1.0× height standard cell structure 100a as shown in FIG. 1A. The circuit region 604 further includes two 1.5× height standard cell structures 608a, 608b, each of which may be the 1.5× height standard cell structure 300a shown in FIG. 3A. Alternatively, the 1.5× height standard cell structures 608a, 608b may be configured as those shown in FIGS. 3B-3D. Circuit region 604 may be configured for an N-P-P-N-N-P dopant-stack architecture. For example, the single unit standard cell structure 606 may be arranged to abut the 1.5× height standard cell structures 608a, and the 1.5× height standard cell structures 608b may be arranged to abut the single unit standard cell structure 610.

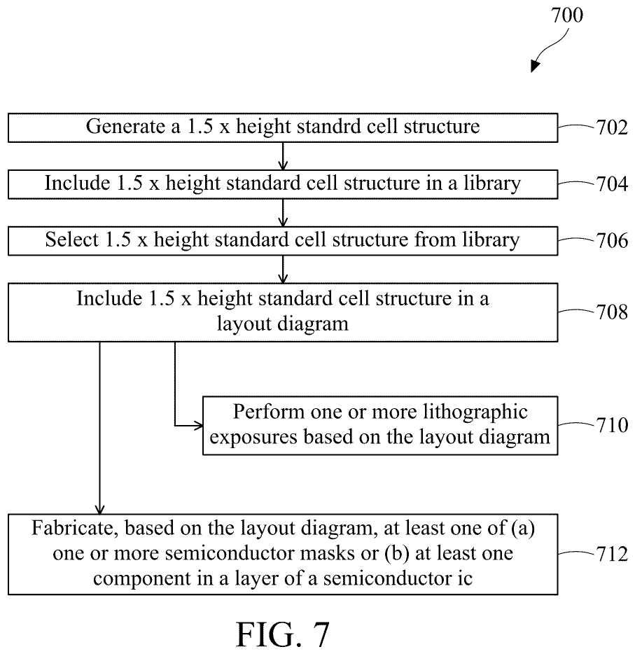

FIG. 7 is a flowchart of a method 700 for generating a layout diagram of a standard cell, in accordance with some embodiments of the present disclosure. The method 700 is implementable, for example, using an electronic design automation (EDA) system. The method 700 includes blocks 702-712. It is understood that additional operations can be provided before, during, and after the method 700, and some of the operations described below can be replaced or eliminated, or be executed in parallel for additional embodiments of the method.

At block 702, a 1.5× height standard cell structure is generated. Examples of such standard cell structures may include those discussed above with respect to FIGS. 3A-3D. At block 704, the 1.5× height standard cell structure is included in a library. At block 706, the 1.5× height standard cell structure is selected from the library. At block 708, the 1.5× height standard cell structure is included in a layout diagram.

From block 708, the flowchart may proceed to block 710 and/or block 712. At block 710, based on the layout diagram, one or more lithographic exposures are performed. For example, fin patterns (for forming OD regions) may be generated. The fin patterns are arranged substantially collinearly with respect to corresponding parallel imaginary first reference lines of a first imaginary grid, the first reference lines lying parallel to a first direction. In some embodiments, the first direction is the horizontal direction. Examples of such fin patterns may be those OD regions shown in FIGS. 1A-3D. The fin patterns are then configured into instances of a first row having a first conductivity and instances of a second row having a second conductivity, the first and second rows being parallel to the first direction. Each instance of the first row and each instance of the second row are configured to include a pre-determined number of the first reference lines. Each instance of the first row is configured to include one or more fin patterns of the first conductivity type. Each instance of the second row is configured to include one or more fin patterns of the second conductivity type. Examples of such rows may be those shown in FIGS. 1A-4, or the like. Thereafter, gate patterns are arranged to overlap corresponding ones of the fin patterns. The gate patterns are arranged substantially collinearly to corresponding parallel imaginary second reference lines of a second imaginary array, the second reference lines lying a second direction, the second direction being substantially perpendicular to the first direction. In some embodiments, the second direction is the vertical direction. Examples of such gate patterns are instances of gate pattern 250 shown in FIGS. 2 and 4.

At block 712, based on the layout diagram, at least one of (A) one or more semiconductor masks or (B) at least one component in a layer of a semiconductor integrated circuit is fabricated. When fabricating semiconductor masks, an electron-beam (e-beam) may be used to form a pattern on a mask based on the layout diagram. The mask is then used in a variety of processes. For example, such a mask may be used in an ion implantation process to form various doped regions in a semiconductor wafer, in an etching process to form various etching regions in semiconductor wafer, and/or other suitable processes.

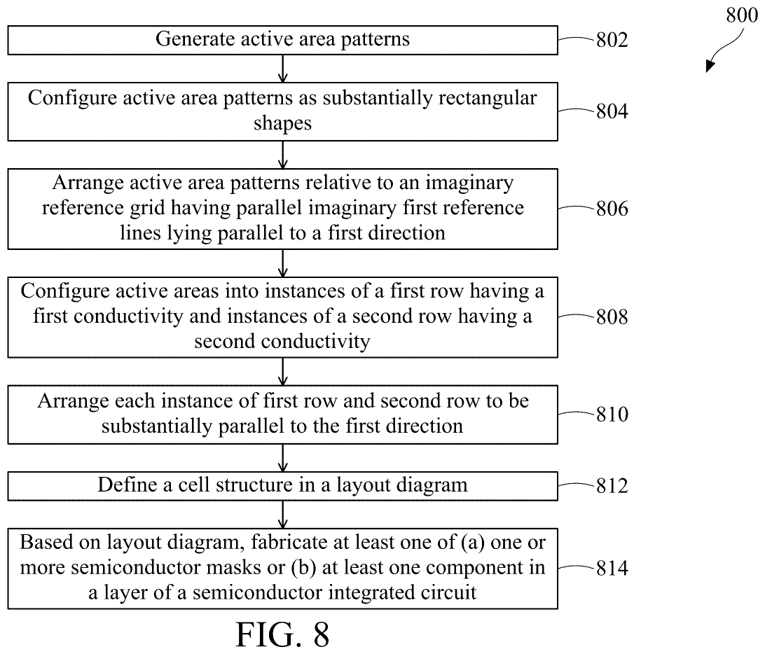

FIG. 8 is a flowchart of a method 800 for generating a layout diagram, in accordance with some embodiments of the present disclosure. The method 800 can be used to generate a 1.0× standard cell structure (e.g., examples shown in FIGS. 1A and 1B), a 1.5× standard cell structure (e.g., examples shown in FIGS. 3A-3D), a 2.0× standard cell structure (e.g., examples shown in FIGS. 1C, 1D, and 1E), or the like, either in uniform-width or non-uniform width. It is understood that additional operations can be provided before, during, and after the method 800, and some of the operations described below can be replaced or eliminated, or be executed in parallel for additional embodiments of the method.

At block 802, active area patterns (e.g., OD regions) are generated. At block 804, the active area patterns are configured as pre-determined shapes, such as substantially rectangular shapes. At block 806, the active area patterns are arranged relative to an imaginary reference grid which includes parallel first imaginary reference lines lying parallel to a first direction (e.g., horizontal direction). At block 808, the active area patterns are configured into instances of a first row having a first conductivity and instances of a second row having a second conductivity. At block 810, each instance of the first row and the second row is arranged to be substantially parallel to the first direction. Each instance of the first row and the second row includes a pre-determined number of the first imaginary reference lines, such as the imaginary reference lines 101 shown in FIGS. 1A-2, or imaginary reference lines 201 shown in FIG. 3A-3D.

At block 812, a cell structure is defined in a layout diagram. In one embodiment, the cell structure is defined to be a 1.5× height standard cell structure in a layout diagram such that a N-type cell region is contiguous with a P-type cell region, where the sum of the heights of the N-type cell region and the P-type cell region in a vertical direction represents a unit height of 1.5×. such as the 1.5× height standard cell structure 300a shown in FIG. 3A. In some embodiments, the cell structure is defined to be a 1.0× height standard cell structure in a layout diagram, such as the cell structures shown in FIGS. 1A and 1B. In some embodiments, the cell structure is defined to be a 2.0× height standard cell structure in a layout diagram, such as the cell structures shown in FIGS. 1C, 1D, and 1E. At block 814, based on the layout diagram, at least one of (A) one or more semiconductor masks or (B) at least one component in a layer of a semiconductor integrated circuit is fabricated.

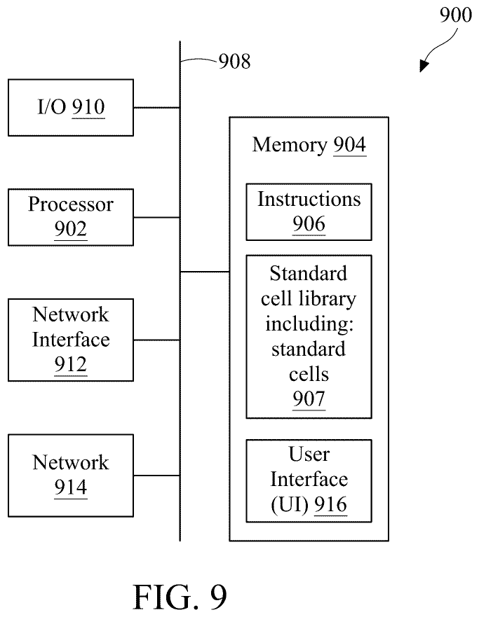

FIG. 9 is a block diagram of an electronic design automation (EDA) system 900 that can be used to practice various embodiments of the present disclosure. In some embodiments, the EDA system 900 includes an automated place-and-route (APR) system. The method of flowchart 700 of FIG. 7 is implemented, for example, using EDA system 900, in accordance with some embodiments, in order to generate a uniform-width, 1.5× standard cell structure, such as those shown in FIGS. 3A-3D, as well as other standard cell structures, such as those shown in FIGS. 1A-1E. In some embodiments, the EDA system is a general purpose computing device including a hardware processor 902 and a non-transitory, computer-readable storage medium 904. Storage medium 904 is encoded with, or stores, computer program code 906, i.e., a set of executable instructions. Execution of instructions 906 by hardware processor 902 represents an EDA tool which implements a portion or all of the method of FIG. 7, in accordance with one or more embodiments of the present disclosure.

The processor 902 is electrically coupled to computer-readable storage medium 904 via a bus 908. The processor 902 is also electrically coupled to an I/O interface 910 by the bus 908. A network interface 912 is also electrically connected to the processor 902 via the bus 908. The network interface 912 is connected to a network 914 so that the processor 902 and computer-readable storage medium 904 are capable of connecting to external elements via the network 914. The processor 902 is configured to execute the computer program code 906 encoded in the computer-readable storage medium 904 in order to cause the EDA system 900 to be usable for performing a portion or all of the method of FIG. 7. In some embodiments, the processor 902 is a central processing unit (CPU), a multi-processor, a distributed processing system, an application specific integrated circuit (ASIC), and/or a suitable processing unit.

In some embodiments, the computer-readable storage medium 904 is an electronic, magnetic, optical, electromagnetic, infrared, and/or a semiconductor system (or apparatus or device). For example, the computer-readable storage medium 904 includes a semiconductor or solid-state memory, a magnetic tape, a removable computer diskette, a random-access memory (RAM), a read-only memory (ROM), a rigid magnetic disk, and/or an optical disk. In some embodiments using optical disks, computer-readable storage medium 904 includes a compact disk-read only memory (CD-ROM), a compact disk-read/write (CD-R/W), and/or a digital video disc (DVD).

In some embodiments, the storage medium 904 stores computer program code 906 configured to cause the EDA system 900 to be usable for performing a portion or all of the method in FIG. 7. In some embodiments, the storage medium 904 also library 907 of standard cells including standard cell structures discussed above with respect to FIGS. 1A-5. The EDA system 900 includes I/O interface 910. The I/O interface 910 is coupled to external circuitry. In some embodiments, the I/O interface 910 includes a keyboard, keypad, mouse, touchscreen, and/or other cursor direction keys for communicating information and commands to the processor 902. The EDA system 900 also includes the network interface 912 coupled to the processor 902. The network interface 912 allows the EDA system 900 to communicate with the network 914, to which one or more other computer systems are connected. The network interface 912 includes wireless network interfaces such as BLUETOOTH, WIFI, WIMAX, GPRS, or WCDMA; or wired network interfaces such as ETHERNET, USB, or IEEE-1364.

The EDA system 900 is configured to receive information through I/O interface 910. The information received through I/O interface 910 includes one or more of instructions, data, design rules, libraries of standard cells, and/or other parameters for processing by the processor 902. The information is then transferred to the processor 902 via the bus 908. The EDA system 900 is configured to receive information related to a user interface (UI) 916 through the I/O interface 910. The information is stored in the computer-readable medium 904 as UI 916. In some embodiments, a portion or all of the method in FIG. 7 is implemented as a standalone software application for execution by a processor, and the software may be a portion of the EDA tool. In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

Various embodiments of the present disclosure provide an approach to increase OD density on an integrated circuit by combining a 1.5× height standard cell structure with 1.0× height standard cell structures in a layout diagram, which minimizes dummy OD regions. The use of 1.5× height standard cell structures is advantageous for optimization of cell combination in a layout diagram of an IC as it allows direct abutment with standard cell structures having different cell heights and/or OD widths with reduced or minimal dummy area.

An embodiment is a semiconductor device. The semiconductor device structure includes active areas on a substrate and arranged relative to an imaginary grid having first and second imaginary reference lines which are substantially parallel to corresponding orthogonal first and second directions, wherein the active areas are organized into instances of a first row having a first conductivity type and instances of a second row having a second conductivity type, and each instance of the first row and the second row comprises a pre-determined number of the first imaginary reference lines. The semiconductor device also includes a first cell region having a first instance of the first row of the active area, and a second cell region having a first instance of the second row of the active area, wherein the second cell region is in direct contact with the first cell region, and wherein the first cell region has a first height and the second cell region has a second height, and a sum of the first and second heights along the second direction represents a unit height of approximately 1.5 times on the imaginary grid.

Another embodiment is a layout diagram for fabricating an integrated circuit. The layout diagram includes a first block representing a first cell region having a first conductivity type, the first cell region having a first height, a second block representing a second cell region having a second conductivity type. The second cell region has a second height equal to the first height, and the second block is contiguous with a first side of the first block. The first and second heights have a unit height of approximately 1.5 times on an imaginary grid having first and second imaginary reference lines which are substantially parallel to corresponding orthogonal first direction and second direction. The layout diagram also includes a third block representing a third cell region having the first conductivity type. The third block is contiguous with a second side of the first block, and the third cell region having a unit height of 1.0 times on the imaginary grid.

A further embodiment is a method for generating a layout diagram, the layout diagram being stored on a non-transitory computer-readable medium. The method includes generating fin patterns, comprising arranging the fin patterns relative to an imaginary grid having first and second imaginary reference lines which are substantially parallel to corresponding orthogonal first and second directions. The method also includes configuring the fin patterns into instances of a first row having a first conductivity type and instances of a second row having a second conductivity type. The method also includes generating gate patterns, comprising arranging the gate patterns substantially parallel to the second direction, and arranging the gate patterns to overlap corresponding ones of the fin patterns. The method further includes defining a first cell structure as a 1.5 times height standard cell structure including one instance of a first cell region configured for the first conductivity type and one instance of a second cell region configured for the second conductivity type.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
active areas on a substrate and arranged relative to an imaginary grid having first and second imaginary reference lines which are substantially parallel to corresponding orthogonal first and second directions, wherein the active areas are organized into instances of a first row having a first conductivity type and instances of a second row having a second conductivity type, and each instance of the first row and the second row comprises a pre-determined number of the first imaginary reference lines;
a first cell region having a first instance of the first row of the active area; and
a second cell region having a first instance of the second row of the active area, the second cell region being in direct contact with the first cell region,
wherein the first cell region has a first height and the second cell region has a second height, and a sum of the first and second heights along the second direction represents a unit height of approximately 1.5 times on the imaginary grid.

2. The semiconductor device of claim 1, wherein the first and second cell regions are arranged in a N-P-P stack architecture along the second direction.

3. The semiconductor device of claim 2, wherein the active areas are arranged in a prefixed N-P-P-N-N-P-P-N stack architecture along the second direction over the first imaginary reference lines.

4. The semiconductor device of claim 1, wherein the first imaginary reference lines are equally separated in a parallel relationship along the second direction.

5. The semiconductor device of claim 1, wherein the first instance of the first row of the active area in the first cell region has a first width, and the first instance of the second row of the active area in the second cell region has a second width that is substantially equal to the first width.

6. The semiconductor device of claim 1, further comprising:
a third cell region in direct contact with the first cell region, the third cell region having a second instance of the first row of the active area.

7. The semiconductor device of claim 6, wherein the second instance of the first row of the active area in the third cell region has a third width, and the third width is substantially equal to the first width.

8. The semiconductor device of claim 1, further comprising:
a fourth cell region having a third instance of the first row of the active area, wherein the fourth cell region is in direct contact with the second cell region.

9. The semiconductor device of claim 8, further comprising:
a fifth cell region having a second instance of the second row of the active area, wherein the fifth cell region is in direct contact with the fourth cell region.

10. The semiconductor device of claim 9, wherein the fourth cell region has a third height and the fifth cell region has a fourth height, and a sum of the third and fourth heights along the second direction represents a unit height of 1.5 times.

11. A layout diagram for fabricating an integrated circuit, comprising:
a first block representing a first cell region having a first conductivity type, the first cell region having a first height;
a second block representing a second cell region having a second conductivity type, the second cell region having a second height equal to the first height, and the second block being contiguous with a first side of the first block, and the first and second heights having a unit height of approximately 1.5 times on an imaginary grid having first and second imaginary reference lines which are substantially parallel to corresponding orthogonal first direction and second direction; and
a third block representing a third cell region having the first conductivity type, the third block being contiguous with a second side of the first block, and the third cell region having a unit height of approximately 1.0 times on the imaginary grid.

12. The layout diagram of claim 11, further comprising:
a fourth block representing a fourth cell region having the first conductivity type, the fourth cell region having a third height that is different than the first height.

13. The layout diagram of claim 12, further comprising:
a first oxide diffusion (OD) region disposed in the first cell region, the first OD region having a first width.

14. The layout diagram of claim 13, further comprising:
a second OD region disposed in the third cell region, the second OD region having a second width that is different than the first width.

15. The layout diagram of claim 13, further comprising:
a third OD region disposed in the fourth cell region, the third OD region having a third width that is different than the first width.

16. The layout diagram of claim 15, wherein an upper boundary of the first OD region and the third OD region are substantially collinear.

17. The layout diagram of claim 16, further comprising:
a dummy OD region disposed between and in contact with the first OD region and the third OD region.

18. A method for generating a layout diagram, the layout diagram being stored on a non-transitory computer-readable medium, the method comprising:
generating fin patterns, comprising:
arranging the fin patterns relative to an imaginary grid having first and second imaginary reference lines which are substantially parallel to corresponding orthogonal first and second directions;
configuring the fin patterns into instances of a first row having a first conductivity type and instances of a second row having a second conductivity type;
generating gate patterns, comprising:
arranging the gate patterns substantially parallel to the second direction; and
arranging the gate patterns to overlap corresponding ones of the fin patterns; and
defining a first cell structure as a 1.5 times height standard cell structure including one instance of a first cell region configured for the first conductivity type and one instance of a second cell region configured for the second conductivity type.

19. The method of claim 11, further comprising:
fabricating, based on the layout diagram, one or more semiconductor mask or at least one component in a layer of a semiconductor integrated circuit.

20. The method of claim 11, wherein the first cell region and the second cell region are arranged in a N-P-P stack architecture along the second direction.
